(19) United States
(12) Patent Application Publication
(10) Pub. No.: US 2005/0229857 A1
(43) Pub. Date: Oct. 20, 2005

(54) Support fixture for semiconductor wafers and associated fabrication method

(75) Inventors: David A. Beauchaine, Vancouver, WA (US); Aaron S. Newton, Vancouver, WA (US)

Correspondence Address: ALSTON & BIRD LLP;BANK OF AMERICA PLAZA, 101 SOUTH TRYON STREET, SUITE 4000, CHARLOTTE, NC, 28280-4000, US

(73) Assignee: SEH America, Inc., Vancouver, WA (US)

(21) Appl. No.: 10/826,730

(22) Filed: Apr. 16, 2004

(51) Int. Cl. C23C 16/00

(52) U.S. Cl. 118/728; 427/249.1

(57) ABSTRACT

A support fixture is provided that includes a boat, a first layer deposited on at least a portion of the boat that has fewer impurities than the boat, and a second layer deposited on at least a portion of the first layer that is formed of a material having one or both of a hardness and a coefficient of thermal expansion that more closely matches the material properties of the wafers to be carried by the support fixture than does those of the boat and the first layer. For example, the boat and the first layer may be formed of silicon carbide and the second layer may be formed of polysilicon. A method of fabricating a support fixture having a boat coated with first and second layers, such as by sequential chemical vapor deposition steps, is also provided.

### BACKGROUND OF THE INVENTION

The present invention relates generally to a support fixture, such as a boat, a tower or the like, for semiconductor wafers and an associated method of fabricating the support fixture and, more particularly, a support fixture coated in such a manner to reduce impurities that may otherwise be released by the boat while also reducing the likelihood of slip generation in the semiconductor wafers.

During a conventional wafer fabrication process, wafers are sometimes held in position by a support fixture. For example, some steps of a wafer fabrication process permit batch processing of a plurality of wafers, thereby necessitating support fixtures capable of holding the plurality of wafers in fixed relative positions. A conventional support fixture utilized during an annealing process is a boat or tower, hereinafter generically and collectively referenced as a boat, that is typically designed to hold a plurality of wafers while the wafers are annealed or during a diffusion process. Similar boats may be utilized in epitaxial reactors to facilitate the growth of epitaxial layers, in diffusion furnaces to facilitate the growth of thin films, or in furnaces conducting elevated temperature anneal cycles upon the semiconductor wafers.

While boats may be fabricated in various manners, a conventional boat has a pair of opposed endplates interconnected by a plurality of rails, such as three or four rails for many conventional boats. The plurality of rails extend between and are connected to the endplates at angularly spaced positions about the periphery of the endplates. Regardless of the number, the rails are generally located at angularly spaced positions that extend about approximately 180°, typically slightly more than 180°, of the endplates. The inwardly facing surfaces of the rails generally define a plurality of slots along their length. The rails define the plurality of slots such that respective slots defined by each of the rails are aligned with one another in a common plane, generally parallel to the endplates. The slots defined by the rails are typically spaced closely to one another. Thus, a relatively large number of wafers may be carried by a respective boat, with peripheral portions of each wafer inserted within and engaged by respective slots defined by the rails. As such, the boat can hold a plurality of wafers in predefined positions relative to each other. In this regard, the boat holds the wafers such that the wafers are generally spaced at least somewhat from one another to facilitate appropriate processing of the wafers.

Once the wafers have been loaded into a boat, the boat may be placed within a furnace for annealing or for a diffusion process, an epitaxial reactor for deposition of an epitaxial layer or within various other chambers utilized during conventional semiconductor processing operations that require a plurality of wafers to be held in a precise manner relative to one another and relative to the interior of the chamber.

Boats have been formed of various materials. For example, boats have been formed of silicon, such as monocrystalline silicon as well as polysilicon. Silicon boats are quite expensive, thereby adding undesirably to the cost associated with fabrication of the semiconductor wafers. Silicon boats are also somewhat brittle and may lack the desired strength, thereby increasing the likelihood that some portion of a silicon boat will break during the handling that is required to, for example, load and unload the wafers, and insert the boat into and withdraw the boat from a furnace. As such, boats formed of silicon carbide have been provided to overcome some of the shortcomings of silicon boats. Silicon carbide boats are less expensive, less brittle and stronger than silicon boats. However, boats formed of silicon carbide also generally include at least some impurities, such as metals. Once subjected to the elevated temperatures within a furnace, an epitaxial reactor or the like, at least some of the impurities tend to be released. Once released by the silicon carbide boat, the impurities may deposit on at least some of the wafers carried by the boat. These impurities may adversely affect the wafer and, more particularly, the performance of the semiconductor devices that may be eventually formed upon the wafer. With the more stringent performance requirements being imposed upon semiconductor wafer manufacturers, the release of impurities, such as metals, by a boat and the subsequent deposition of the impurities upon the wafer is becoming increasingly disfavored.

To address the release of impurities from a silicon carbide boat, silicon carbide boats have been coated with a silicon carbide layer. This silicon carbide layer is typically deposited by chemical vapor deposition and generally has a greater purity, and therefore less impurities, than the underlying silicon carbide boat. While the silicon carbide layer reduces the release of impurities from the silicon carbide boat, this boat still disadvantageously causes slip within at least some of the wafers carried thereby. In this regard, the wafers are formed of a different material than the silicon carbide boat. For example, the wafers may be formed of silicon which has a differentthermal expansion coefficient and hardness than that of the silicon carbide that forms the boat. With respect to hardness, the silicon carbide boat is approximately twice as hard as a silicon wafer. Therefore, any irregularities on the portion of the boat that contacts the wafer, such as within the slots defined by the rails, may cause a micro-scratch on the wafer that results in a strained condition. Strained conditions can also be created within the wafer in instances in which the wafer sticks to the boat or otherwise does not slide easily within the slots defined by the rails as the silicon carbide boat expands and contracts at a different rate than the silicon wafer upon exposure to elevated temperatures. When a wafer is subjected to a strained condition while at elevated temperatures, the strain may be relieved by the generation of slip within the wafer. As known to those skilled in the art, wafers suffering from slip have reduced performance characteristics which may, in turn, reduce the yield achieved by the fabrication process.

As such, it would be desirable to provide an improved boat that is strong, but not brittle. Moreover, it would be desirable to provide an improved boat that does not release any significant measure of impurities and which is designed so as to reduce the likelihood of slip generation within the wafers carried by the boat. As such, the quality of the wafers carried by the boat can be maintained and the yield will not suffer.

### BRIEF SUMMARY OF THE INVENTION

An improved support fixture is thereby provided that does not release impurities of any significant measure and that also reduces the likelihood of slip generation within the wafers carried by the support fixture relative to conventional support fixtures. Additionally, the improved support fixture is quite strong and is not as brittle as silicon or polysilicon boats so as to withstand repeated use during semiconductor fabrication operations.

A support fixture for holding at least one wafer and, more typically, a plurality of wafers is provided that includes a boat, advantageously formed of silicon carbide or graphite. The support fixture also includes a first layer on at least a portion of the boat. The first layer is generally formed of the same material as the boat, such as silicon carbide. However, the first layer generally has fewer impurities than the boat. The first layer generally surrounds the boat so as to reduce the impurities that are released from the boat since the boat is surrounded by the higher purity, first layer. In this regard, the first layer may effectively prevent most, if not all, of the impurities within the boat from being released during use of the support fixture, even at elevated temperatures. By significantly reducing the impurities released by the support fixture and, in particular, the boat, fewer impurities are deposited upon the wafers, thereby improving the performance of the resulting wafers and consequently improving the yield of the wafer fabrication process.

01 The support fixture also includes a second layer on at least a portion of the first layer. The second layer is advantageously formed of a material having: (i) a hardness that more closely matches the hardness of the wafer(s) than does the hardness of the boat, and/or (ii) a coefficient of thermal expansion that more closely matches the coefficient of thermal expansion of the wafer(s) than does the coefficient of thermal expansion of the boat. For example, the second layer may be formed of polysilicon in instances in which the boat is to carry one or more silicon wafers. By more closely matching the hardness of the wafers, the second layer permits the wafers to slide or otherwise move more easily relative to the boat without scratching the wafer, thereby reducing the potential for slip generation. Additionally, by more closely matching the coefficient of thermal expansion of the wafers, the second layer acts as a buffer between the wafer and the boat, thereby also providing strain isolation to the wafer, particularly at the elevated temperatures within the furnace, epitaxial reactor or other heated chamber within which the support fixture is disposed.

A method of fabricating a support fixture is also provided in which a boat, typically formed of silicon carbide or graphite, is initially provided. The boat is then at least partially and, more typically, completely coated with a first layer that may be formed of the same material as the boat, such as silicon carbide. The first layer may be deposited upon the boat by chemical vapor deposition. As such, the purity of the first layer may be enhanced relative to the purity of the boat such that the first layer can effectively reduce the release of impurities from the boat relative to those released by an uncoated boat. According to the method of this aspect of the present invention, a second layer is then deposited on at least a portion of the first layer. The second layer is comprised of a material having a hardness that more closely matches that of the wafers to be carried by the support fixture than does the hardness of the boat, and/or a coefficient of thermal expansion that more closely matches the coefficient of thermal expansion of the wafers to be carried by the support fixture than does the coefficient of thermal expansion of the boat. For example, a second layer of polysilicon may be deposited in instances in which the support fixture will carry silicon wafers. As such, the second layer reduces the likelihood of slip generation within the wafers carried by the resulting support fixture. Like the first layer, the second layer is generally deposited by chemical vapor deposition.

An improved support fixture and method of fabrication are thereby provided. The support fixture generally releases fewer impurities and is less likely to generate slip within the wafers carried by the support fixture than conventional support fixtures. Thus, the performance characteristics of the resulting wafers may be improved and the yield of the wafer fabrication process may correspondingly be enhanced. Since the boat may be formed silicon carbide, the resulting support fixture may also be stronger and less brittle than conventional silicon boats.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a perspective view of a support fixture according to one embodiment of the present invention; and

FIG. 2 is a fragmentary cross-sectional view of a portion of one rail of the support fixture of FIG. 1; and

FIG. 3 is a flow chart illustrating the operations performed during fabrication of a support fixture according to one embodiment of the present invention.

### DETAILED DESCRIPTION OF THE PREFERRED EMBODIMENTS

The present inventions now will be described more fully hereinafter with reference to the accompanying drawings, in which some, but not all embodiments of the invention are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

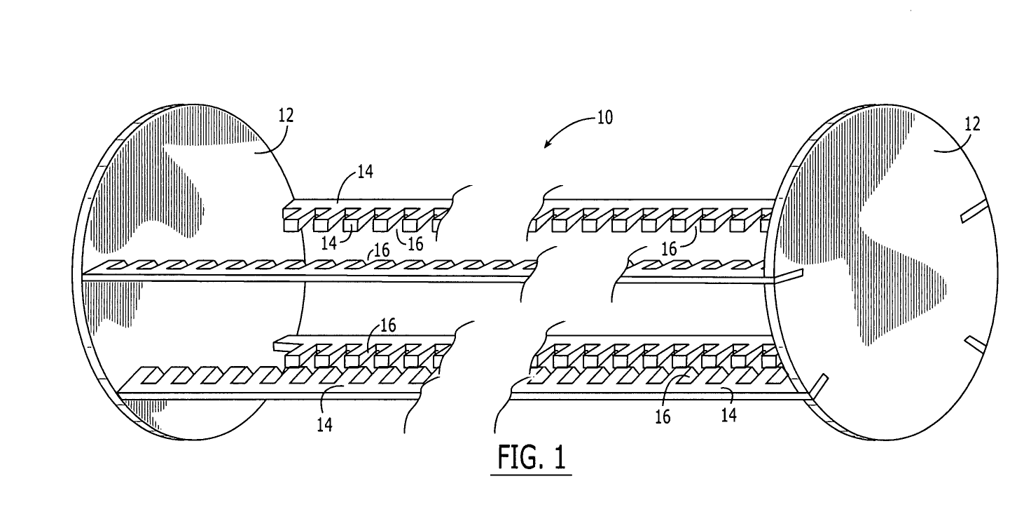

A support fixture 10 according to one embodiment of the present invention is depicted in FIG. 1. According to the present invention, the support fixture includes a boat, a tower or the like, all of which will be generically and collectively referenced hereinafter as a boat. Although a boat designed to carry a plurality of wafers will be subsequently described by way of example, the boat may, instead, be designed to carry a single wafer. In addition, although the boat may be constructed in many different manners, the boat of the illustrated embodiment has a pair of endplates 12 and a plurality of rails 14 extending therebetween. The boat may include any number of rails, but generally includes three or four rails spaced apart from one another. In this regard, the rails are generally connected to peripheral portions of the endplates and are spaced angularly relative to one another such that all of the rails extend about an angle of about 180°, typically slightly more than 180° as shown in FIG. 1.

The inwardly facing surfaces of the rails 14 generally define a plurality of slots 16 along their length. These slots have a width that is slightly greater than the thickness of the wafers to be carried by the support fixture 10. Additionally, the slots are defined by the rails in such a manner that each slot of one rail is aligned with respective slots defined by the other rails in a common plane. As such, a wafer can be inserted into the respective slots and held securely therein during one or more operations of a wafer fabrication process. The boat may define any number of slots along the length of the rails. In this regard, the rails of a boat need only define a single slot such that the support fixture can carry a single wafer. However, support fixtures are generally designed to carry a plurality of wafers during a batch processing operation and therefore correspondingly define a plurality of slots along the length of the respective rails. The slots are also generally evenly spaced at a predefined pitch, although other spacings, including uneven spacings, are permitted, if desired. In one embodiment, for example, the rails define 128 slots with a pitch of 0.1875 inches. However, the spacing between adjacent slots may vary depending upon the requirements of the particular step in the fabrication process that will be conducted while the wafers are carried by the support fixture.

Although one embodiment of a support fixture 10 is described above and depicted in FIG. 1, the boat may be differently configured without departing from the spirit and scope of the present invention. For example, although the boat described above and illustrated in FIG. 1 has a plurality of rails 14 extending between the end plates 12, the boat may include a single arcuate member extending between and connected to the periphery of the opposed end plates. This arcuate member could similarly define one or more slots for receiving and supporting respective wafers.

Regardless of its configuration, the support fixture 10 may be utilized to carry wafers during various operations of a semiconductor wafer fabrication process. For example, the support fixture may be utilized to hold wafers in a furnace while the wafers are being annealed or during a diffusion process. Alternatively, the support fixture may be utilized to hold wafers within a reactor chamber while epitaxial layers are deposited upon the wafers. Moreover, while the support fixture will be described herein as being designed to carry semiconductor wafers during the fabrication of the semiconductor wafers themselves, the support fixture can carry wafers during other fabrication processes, such as during the fabrication of integrated circuits or solar cells upon the wafers.

Although the boat may be formed of various materials, such as graphite, the boat and, in particular, the rails 14 and the opposed endplates 12 of one advantageous embodiment are formed of silicon carbide. As known to those skilled in the art, silicon carbide is relatively strong and boats formed of silicon carbide are less brittle than corresponding boats formed of silicon or polysilicon. Thus, boats formed of silicon carbide are generally more robust and are not damaged as easily during handling, such as while loading or unloading the wafers and/or inserting or withdrawing the support fixture from a furnace, a reaction chamber or the like. Additionally, boats formed of silicon carbide are generally less expensive than corresponding support fixtures formed of silicon.

As known to those skilled in the art, silicon carbide boats are conventionally formed by slip casting in which the end plates 12 and rails 14 are separately formed of silicon carbide. Slots may be defined about the periphery of the end plates to receive end portions of the rails. Slurry containing silicon carbide may be applied about the junction of the rails and the end plates such that subsequent firing or other heat treatment of the boat effectively integrates the end plates and the rails.

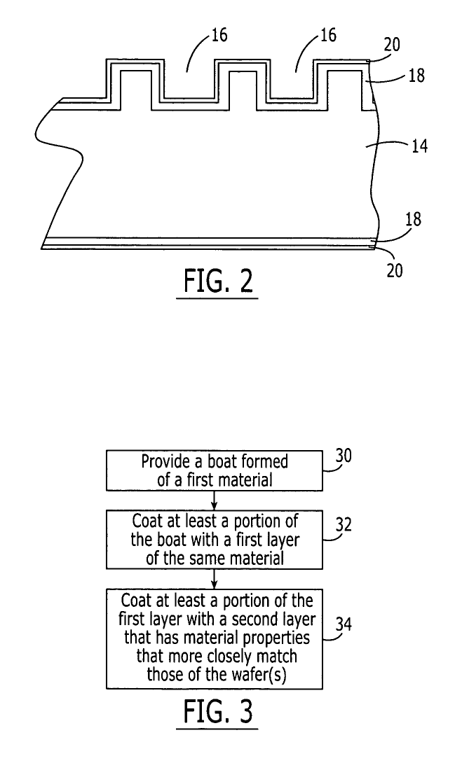

In order to significantly reduce the impurities, such as metal impurities, released by the boat during use of the support fixture 10 in various wafer fabrication operations, and, in particular, those wafer fabrication operations conducted at elevated temperatures, a first layer 18 is advantageously deposited upon at least a portion of the boat and, more preferably, upon the entire boat so as to surround the boat. See, for example, FIG. 2 which depicts in cross-section a portion of a rail 14 coated with the first layer. The first layer is generally formed of the same material as the boat, such as silicon carbide. However, the first layer has a greater purity than the boat. For example, a conventional boat formed of silicon carbide generally has various impurities including various metal impurities, such as 3.8 parts per million (ppm) by weight of iron, less than 0.4 ppm by weight of iron and 12.9 ppm by weight of aluminum. In contrast, a first layer of silicon carbide deposited, such as via chemical vapor deposition, upon the boat generally has fewer impurities overall including fewer metal impurities, such as 0.013 ppm by weight of iron, less than 0.008 ppm by weight of copper and 0.09 ppm by weight of aluminum. By having substantially fewer impurities, the first layer does not release many impurities during use of the support fixture including use of the support fixture at elevated temperatures, such as during annealing, diffusion processes, epitaxial deposition or the like. Additionally, the first layer effectively prevents most, if not all, of the impurities within the boat from being released during use of the support fixture, even at elevated temperatures. By significantly reducing the impurities released by the support fixture and, in particular, the boat, fewer impurities are deposited upon the wafers, thereby improving the performance of the resulting wafers and consequently improving the yield of the wafer fabrication process.

As noted above, the first layer 18 is generally deposited upon a boat by chemical vapor deposition in a conventional manner. See steps 30 and 32 of FIG. 3. The thickness of the first layer generally depends upon the process conditions, such as the time and temperature to which the support fixture will be subjected once in use, as well as the diffusion coefficients for the various impurities within the boat. The first layer of one embodiment generally has a thickness of about 10 microns or less. However, the first layer may have various thicknesses with thicker layers providing somewhat greater reduction in the impurities that are released but being more expensive and time consuming to fabricate, and thinner layers permitting slightly more impurities to be released from the boat but being less expensive and being capable of being fabricated more rapidly.

According to the present invention, a second layer 20 is advantageously deposited, also typically via chemical vapor deposition as shown by step 34 of FIG. 3, upon at least a portion of the first layer 18. See FIG. 2. The second layer is comprised of a material having different material properties than the boat. In this regard, the second layer of the support fixture 10 of one advantageous embodiment has a hardness that more closely matches the hardness of the wafers than does the hardness of the boat and the first layer. As used herein, a material property of the second layer is considered to more closely match that of the wafers in instances in which the material property of the second layer is closer to (or, in other words, differs less from) that of the wafers than does the comparable material property of the boat. In one embodiment, however, the second layer has a hardness that matches, or equals, the hardness of the wafers. Additionally, or alternatively, the second layer of one advantageous embodiment may have a coefficient of thermal expansion that more closely matches the coefficient of thermal expansion of the wafers than does the coefficient of thermal expansion of the material that forms the boat and the first layer, such as the coefficient of thermal expansion of silicon carbide. Preferably, the second layer is formed of a material having a coefficient of thermal expansion that matches the coefficient of thermal expansion of the wafers. For a support fixture 10 designed to carry silicon wafers, for example, the second layer may be formed of polysilicon having both a hardness and a coefficient of thermal expansion that more closely match the hardness and coefficient of thermal expansion of the silicon wafers.

As shown in FIG. 2, the second layer 20 is generally the outermost layer and therefore contacts edge portions of the wafers. In embodiments in which the hardness of the second layer more closely matches that of the wafers, the wafers can slide or otherwise move more easily relative to the boat and, with respect to the illustrated embodiment of the boat, within the slots 16 defined by the rails 14. As such, the support fixture 10 is less likely to scratch the wafers and accordingly reduces the potential for slip generation. Moreover, in embodiments in which the coefficient of thermal expansion of the second layer more closely matches that of the wafers, the second layer expands and contracts in much more similar proportions to the wafers than does the boat during processing of the wafers at elevated temperatures. The second layer thus acts as a buffer between the wafers and the boat and provides a measure of strain isolation between the wafers and the boat. Thus, less stress and other deleterious forces will be placed upon the wafers, than is placed upon the wafers that are carried by support fixtures formed of materials that have coefficients of thermal expansion that do not match that of the wafers, such as silicon wafers carried by a silicon carbide boat. Since less stress is placed upon the wafers, the support fixture 10 of the present invention is less likely to create slip within the wafer, especially while the wafers are at elevated temperatures and more prone to experience slip. By reducing slip generation, the wafers carried by the support fixture of the present invention will, on average, be of higher quality and have improved performance characteristics, thereby potentially improving the yield of the semiconductor wafer fabrication process.

The second layer is typically deposited upon the entirety of the first layer 18 so as to surround the boat. However, the second layer need not be deposited upon all portions of the first layer, but, instead, only upon those portions of the support fixture 10 that will be in contact with the wafers, such as the inwardly facing, slotted surfaces of the rails 14.

As noted above, the second layer is also advantageously deposited via chemical vapor deposition. This chemical vapor deposition process may be conducted in a conventional manner, but is typically conducted at a temperature between 575° C. and 725° C. and, more typically at a temperature of about 650° C. The second layer may also have various thicknesses, although the support fixture 10 of one embodiment includes a second layer having a thickness of about 5 microns.

By coating a boat with a first layer formed of the same material as the boat but having fewer impurities and, in turn, coating the boat with a second layer formed of a material having a hardness and/or a coefficient of thermal expansion that more closely matches the corresponding material properties of the wafers, the wafers carried by the support fixture 10 generally have improved performance characteristics as compared to those carried by conventional support fixtures. In this regard, fewer impurities are generally released from the boat and deposited upon the wafers and the possibility of slip generation within the wafers is reduced. As such, the yield of the resulting semiconductor wafer fabrication process may be increased relative to comparable processes utilizing conventional support fixtures. Additionally, the support fixture of the present invention may be fabricated in a relatively economical manner by utilizing conventional chemical vapor deposition technology conducted within conventional reaction chambers.

Further, the resulting support fixture 10 can be readily cleaned following use so as to remove materials that have been deposited or otherwise built upon the support fixture in the same manner that other fixtures and tools are cleaned since the outer surface of the support fixture of the present invention is generally comprised of polysilicon. In this regard, the support fixture may be cleaned with a solution of water and hydrofluoric (HF) acid. Nitric acid may also be added to the cleaning solution to further clean the support fixture. Since the nitric acid will etch the polysilicon layer 20, however, the second layer may need to be redeposited after one or more cleanings to insure that a sufficient coating of polysilicon remains.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

1. A support fixture for holding at least one wafer comprising:
a boat comprised of a material selected from the group consisting of silicon carbide and graphite;
a first layer on at least a portion of said boat and comprised of silicon carbide; and
a second layer on at least a portion of said first layer and comprised of polysilicon.

2. A support fixture according to claim 1 wherein said first layer has a greater purity than said boat.

3. A support fixture according to claim 1 wherein said second layer has a hardness that more closely matches a hardness of the at least one wafer than a hardness of said boat.

4. A support fixture according to claim 1 wherein said second layer has a coefficient of thermal expansion that more closely matches a coefficient of thermal expansion of the at least one wafer than a coefficient of thermal expansion of said boat.

5. A support fixture according to claim 1 wherein said first layer completely surrounds said boat.

6. A support fixture according to claim 1 wherein said first and second layers are chemical vapor deposition layers.

7. A support fixture for holding at least one wafer comprising:
a boat;
a first layer on at least a portion of said boat, wherein said first layer has a greater purity than said boat; and
a second layer on at least a portion of said first layer, wherein said second layer is formed of a different material than said first layer and said boat, and wherein said second layer has at least one material property selected from the group consisting of: (i) a hardness that more closely matches a hardness of the at least one wafer than a hardness of said boat, and (ii) a coefficient of thermal expansion that more closely matches a coefficient of thermal expansion of the at least one wafer than a coefficient of thermal expansion of said boat.

8. A support fixture according to claim 7 wherein said first layer and said boat are comprised of silicon carbide.

9. A support fixture according to claim 7 wherein said second layer is comprised of polysilicon.

10. A support fixture according to claim 7 wherein said first layer completely surrounds said boat.

11. A support fixture according to claim 7 wherein said first and second layers are chemical vapor deposition layers.

12. A method of fabricating a support fixture for holding at least one wafer comprising:
providing a boat comprised of a material selected from the group consisting of silicon carbide and graphite;
depositing a first layer of silicon carbide on at least a portion of said boat; and
depositing a second layer of polysilicon on at least a portion of the first layer.

13. A method according to claim 12 wherein depositing the first layer comprises depositing the first layer so as to completely surround the boat.

14. A method according to claim 12 wherein depositing the first layer comprises depositing the first layer via chemical vapor deposition.

15. A method according to claim 12 wherein depositing the second layer comprises depositing the second layer via chemical vapor deposition.

16. A method of fabricating a support fixture for holding at least one wafer comprising:
depositing a first layer on at least a portion of a boat, wherein depositing the first layer comprises depositing a first layer that has a greater purity than the boat; and
depositing a second layer on at least a portion of the first layer, wherein depositing the second layer comprises depositing a second layer that is formed of a different material than the first layer and the boat and that has at least one material property selected from the group consisting of: (i) a hardness that more closely matches a hardness of the at least one wafer than a hardness of the boat, and (ii) a coefficient of thermal expansion that more closely matches a coefficient of thermal expansion of the at least one wafer than a coefficient of thermal expansion of the boat.

17. A method according to claim 16 wherein the boat is comprised of silicon carbide, and wherein depositing the first layer comprises depositing a first layer comprised of silicon carbide.

18. A method according to claim 16 wherein depositing the second layer comprises depositing a second layer comprised of polysilicon.

19. A method according to claim 16 wherein depositing the first layer comprises depositing the first layer so as to completely surround the boat.

20. A method according to claim 16 wherein depositing the first layer comprises depositing the first layer via chemical vapor deposition.

21. A method according to claim 16 wherein depositing the second layer comprises depositing the second layer via chemical vapor deposition.
